(19) United States
(12) Patent Application Publication
(10) Pub. No.: US 2026/0372144 A1
(43) Pub. Date: Nov. 19, 2026

(54) WIRING SUBSTRATE AND COMPONENT-MOUNTED WIRING SUBSTRATE

(71) Applicant: IBIDEN CO., LTD., Gifu (JP)

(72) Inventor: Masatoshi KUNIEDA, Gifu (JP)

(73) Assignee: IBIDEN CO., LTD., Gifu (JP)

(21) Appl. No.: 19/327,501

(22) Filed: Sep. 12, 2025

Related U.S. Application Data
(63) Continuation of application No. PCT/JP2024/009382, filed on Mar. 11, 2024.

(30) Foreign Application Priority Data
Mar. 14, 2023 (JP) 2023-040032

(51) Int. Cl. H10W 70/68; G02B 6/42; H10W 70/05; H10W 74/10; H10W 90/00; H10W 90/24

(52) U.S. Cl. CPC H10W 70/682; G02B 6/4202; H10W 70/095; H10W 74/117; H10W 90/24; H10W 90/722; H10W 90/724; H10W 90/792

(57) ABSTRACT

A wiring substrate includes an electrical wiring part having a recess and a component mounting region formed in the recess on a component mounting surface of the electrical wiring part, and an optical wiring formed on the component mounting surface of the electrical wiring part such that the optical wiring optically connects to an optoelectronic component. The electrical wiring part has an optoelectronic component mounting region formed such that the component mounting region at least partially overlaps with the optoelectronic component mounting region.

### CROSS-REFERENCE TO RELATED APPLICATIONS

The present application is a continuation of and claims the benefit of priority to International Application No. PCT/JP2024/009382, filed Mar. 11, 2024, which is based upon and claims the benefit of priority to Japanese Application No. 2023-040032 filed Mar. 14, 2023. The entire contents of these applications are incorporated herein by reference.

### BACKGROUND OF THE INVENTION

### Field of the Invention

The present invention relates to a wiring substrate and a component-mounted wiring substrate.

### Description of Background Art

Japanese Patent Application Laid-Open Publication No. 2013-257381 describes an optoelectronic module. The entire contents of this publication are incorporated herein by reference.

### SUMMARY OF THE INVENTION

According to one aspect of the present invention, a wiring substrate includes an electrical wiring part having a recess and a component mounting region formed in the recess on a component mounting surface of the electrical wiring part, and an optical wiring formed on the component mounting surface of the electrical wiring part such that the optical wiring optically connects to an optoelectronic component. The electrical wiring part has an optoelectronic component mounting region formed such that the component mounting region at least partially overlaps with the optoelectronic component mounting region.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a cross-sectional view illustrating an example of a component-mounted wiring substrate according to an embodiment of the present invention;

FIG. 3 is a cross-sectional view illustrating a modified example of a component-mounted wiring substrate according to an embodiment of the present invention;

FIG. 4A is a cross-sectional view illustrating an example of a manufacturing process of a wiring substrate according to an embodiment of the present invention;

FIG. 4B is a cross-sectional view illustrating an example of a manufacturing process of a wiring substrate according to an embodiment of the present invention;

FIG. 4C is a cross-sectional view illustrating an example of a manufacturing process of a wiring substrate according to an embodiment of the present invention;

FIG. 4D is a cross-sectional view illustrating an example of a manufacturing process of a wiring substrate according to an embodiment of the present invention;

FIG. 4E is a cross-sectional view illustrating an example of a manufacturing process of a wiring substrate according to an embodiment of the present invention;

FIG. 4F is a cross-sectional view illustrating an example of a manufacturing process of a wiring substrate according to an embodiment of the present invention;

FIG. 5A is a cross-sectional view illustrating an example of a manufacturing process of a component-mounted wiring substrate according to an embodiment of the present invention;

FIG. 5B is a cross-sectional view illustrating an example of a manufacturing process of a component-mounted wiring substrate according to an embodiment of the present invention;

FIG. 6A is a cross-sectional view illustrating a modified example of a manufacturing process of a component-mounted wiring substrate according to an embodiment of the present invention;

FIG. 6B is a cross-sectional view illustrating a modified example of a manufacturing process of a component-mounted wiring substrate according to an embodiment of the present invention;

FIG. 6C is a cross-sectional view illustrating a modified example of a manufacturing process of a component-mounted wiring substrate according to an embodiment of the present invention;

FIG. 7A is an enlarged cross-sectional view illustrating another embodiment of an example of a manufacturing process of a component-mounted wiring substrate according to an embodiment of the present invention;

FIG. 7B is an enlarged cross-sectional view illustrating another embodiment of an example of a manufacturing process of a component-mounted wiring substrate according to an embodiment of the present invention;

FIG. 8A is an enlarged cross-sectional view illustrating another embodiment of a modified example of a manufacturing process of a component-mounted wiring substrate according to an embodiment of the present invention; and

FIG. 8B is an enlarged cross-sectional view illustrating another embodiment of a modified example of a manufacturing process of a component-mounted wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

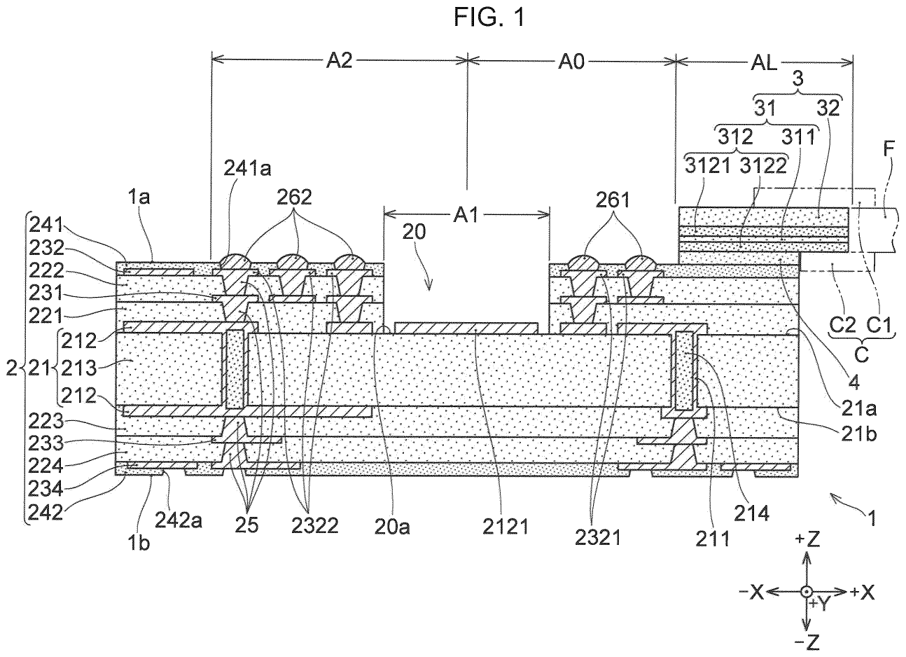

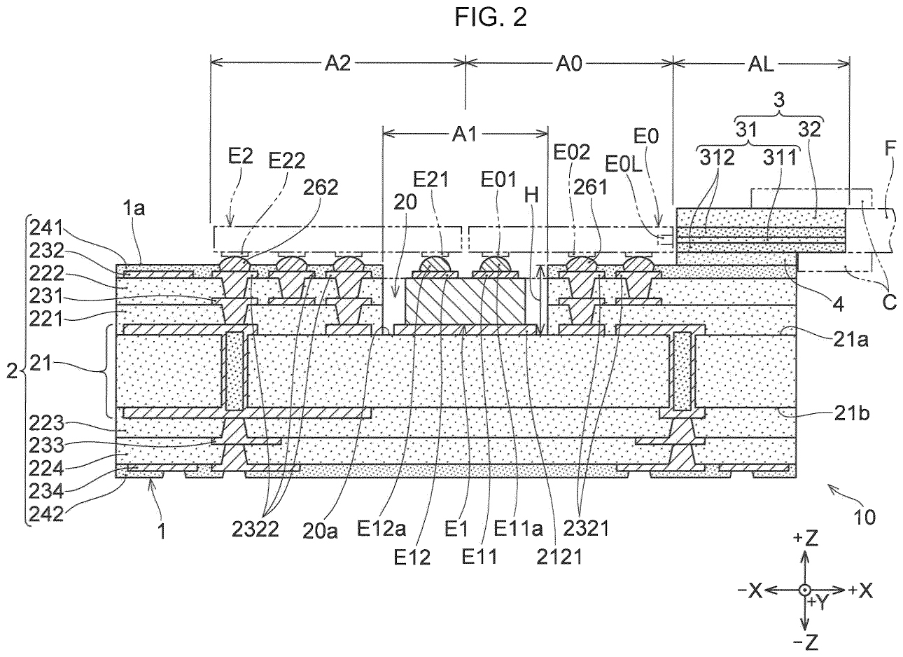

A wiring substrate and a component-mounted wiring substrate according to an embodiment of the present invention are described with reference to the drawings. FIG. 1 illustrates a wiring substrate 1 according to an embodiment of the present invention. FIG. 2 illustrates a component-mounted wiring substrate 10 according to an embodiment of the present invention. The wiring substrate 1 and the component-mounted wiring substrate 10 are merely examples of the wiring substrate and the component-mounted wiring substrate of the present embodiment. A laminated structure, and the number of conductor layers and the number of insulating layers of the wiring substrate or the component-mounted wiring substrate of the embodiment are not limited to the laminated structure of the wiring substrate 1 of FIG. 1 or the component-mounted wiring substrate 10 of FIG. 2, and the number of conductor layers and the number of insulating layers included in the wiring substrate 1 or the component-mounted wiring substrate 10.

As illustrated in FIG. 1, the wiring substrate 1 of the embodiment includes an electrical wiring part 2 and an optical wiring part 3. The wiring substrate 1 has a first surface (component mounting surface) (1a), which is one of two surfaces (main surfaces) orthogonal to a thickness direction thereof, and a second surface (1b), which is the other of the two surfaces (main surfaces) and is on the opposite side with respect to the first surface (component mounting surface) (1a). In the example of FIG. 1, the first surface (1a) of the wiring substrate 1 is constituted by one of two surfaces (main surfaces) of the electrical wiring part 2, and the second surface (1b) of the wiring substrate 1 is constituted by the other of the two surfaces (main surfaces) of the electrical wiring part 2. An optical wiring mounting region (AL) is provided on the component mounting surface (1a) of the wiring substrate 1. The optical wiring part 3 is formed in the optical wiring mounting region (AL).

In the description of the embodiment, a side of the wiring substrate 1 (or the electrical wiring part 2) farther from a center part (an insulating layer 213 of a core substrate 21 to be described later) in the thickness direction is also referred to as an “upper side” or simply “upper,” and a side of the wiring substrate 1 (or the electrical wiring part 2) closer to the center part (the insulating layer 213 of the core substrate 21) in the thickness direction is also referred to as a “lower side” or simply “lower.” Further, for the conductor layers and the resin insulating layers, a surface facing the opposite side with respect to the insulating layer 213 of the core substrate 21 is also referred to as an “upper surface,” and a surface facing the insulating layer 213 of the core substrate 21 side is also referred to as a “lower surface.” The thickness direction of the wiring substrate 1 (see +Z direction and −Z direction in FIG. 1) is also simply referred to as the “Z direction.”

As illustrated in FIG. 1, the wiring substrate 1 of the embodiment is structured to be capable of mounting multiple electronic components. Specifically, the wiring substrate 1 has an optoelectronic component mounting region (A0) where an optoelectronic component (E0) (see FIG. 2) is mounted. Further, the wiring substrate 1 has a first component mounting region (A1) where a first component (E1) (see FIG. 2) is mounted.

The number of components to be mounted on the wiring substrate 1 is not limited to two, but may be three or more. Therefore, the wiring substrate 1 in FIG. 1 has a second component mounting region (A2) where a second component (E2) (see FIG. 2) is mounted. In FIG. 1, the optoelectronic component mounting region (A0), the first component mounting region (A1), and the second component mounting region (A2) are provided in order of proximity to the optical wiring part 3. The formations of the optoelectronic component mounting region (A0), the first component mounting region (A1), and the second component mounting region (A2) are not limited to the example illustrated in FIG. 1, provided that mutual connections can be established between the optoelectronic component (E0) and the first component (E1), and between the first component (E1) and the second component (E2). FIG. 1 illustrates an example in which one component is mounted in each component mounting region. However, it is also possible that two or more components are mounted in each component mounting region.

The optoelectronic component mounting region (A0) includes the optoelectronic component (E0) and conductive connectors and other mounting members used for mounting the optoelectronic component (E0) on the wiring substrate 1. Examples of the other mounting members include a filling resin to be filled between the optoelectronic component (E0) and the electrical wiring part 2, an adhesive for fixing the optoelectronic component (E0) to the wiring substrate 1, and the like. Further, in the wiring substrate 1 of the embodiment, the first component mounting region (A1) includes the first component (E1) and conductive connectors and other mounting members used for mounting the first component (E1) to the wiring substrate 1. Examples of the other mounting members include a filling resin to be filled between the first component (E1) and the wiring substrate 1, and an adhesive for fixing the first component (E1) to the wiring substrate 1. In the example of FIG. 1, the first component mounting region (A1) coincides with a recess formation region of the substrate, which is a recess 20. Further, in the wiring substrate 1 of the embodiment, the second component mounting region (A2) includes the second component (E2) and conductive connectors and other mounting members used for mounting the second component (E2) to the wiring substrate 1. Examples of the other mounting members include a filling resin to be filled between the second component (E2) and the wiring substrate 2, and an adhesive for fixing the second component (E2) to the wiring substrate 1.

As illustrated in FIG. 1, the wiring substrate 1 of the embodiment has the recess 20 on the component mounting surface (1a). The first component mounting region (A1) is within a range in which the recess 20 is formed, and the first component (E1) is positioned in the recess 20 when mounted on the wiring substrate 1. In other words, in the wiring substrate 1 of the embodiment, a non-electrode surface of the first component (E1) positioned in the first component mounting region (A1) is provided below the component mounting surface (1a). The non-electrode surface of the first component (E1) is a surface on which electrodes (E11, E12) of the first component (E1) are not provided, and is on the opposite side with respect to a surface (electrode surface) on which the electrodes (E11, E12) are provided. On the other hand, in the wiring substrate 1 of the embodiment, a non-electrode surface of the optoelectronic component (E0) positioned in the optoelectronic component mounting region (A0) is provided on the component mounting surface (1a).

The non-electrode surface of the optoelectronic component (E0) is a surface on which electrodes (E01, E02) of the optoelectronic component (E0) are not provided, and is on the opposite side with respect to a surface (electrode surface) on which the electrodes (E01, E02) are provided. Further, in the wiring substrate 1 of the embodiment, a non-electrode surface of the second component (E2) positioned in the second component mounting region (A2) is provided on the component mounting surface (1a). The non-electrode surface of the second component (E2) is a surface on which electrodes (E21, E22) of the second component (E2) are not provided, and is on the opposite side with respect to a surface (electrode surface) on which the electrodes (E21, E22) are provided.

In a plan view, the optoelectronic component mounting region (A0) at least partially overlaps with the first component mounting region (A1). That is, the first component mounting region (A1) partially overlaps with the optoelectronic component mounting region (A0). Further, in a plan view, the second component mounting region (A2) at least partially overlaps with the first component mounting region (A1). That is, the first component mounting region (A1) partially overlaps with the second component mounting region (A2). The first component mounting region (A1) partially overlaps with the optoelectronic component mounting region (A0) and also partially overlaps with the second component mounting region (A2). Here, the term “plan view” means viewing an object along the thickness direction (Z direction) of the wiring substrate 1.

In the wiring substrate 1 of the present embodiment, the first component mounting region (A1) is provided in the recess 20 formed in the component mounting surface (1a). The first component mounting region (A1), which is within the range in which the recess 20 is formed, is provided on the component mounting surface (1a) so as to at least partially overlap with the optoelectronic component mounting region (A0). In other words, the optoelectronic component mounting region (A0) is provided on the component mounting surface (1a) so as to at least partially overlap with the first component mounting region (A1), which is within the range in which the recess 20 is formed. When the optoelectronic component mounting region (A0) is provided so as to at least partially overlap with the first component mounting region (A1), when the optoelectronic component (E0) (see FIG. 2) and the first component (E1) (see FIG. 2) are mounted on the wiring substrate 1, the optoelectronic component (E0) and the first component (E1) are connected without going through the electrical wiring part 2, which may result in a less complex structure, easier alignment, and easier connection. When the optoelectronic component (E0) and the first component (E1) are directly connected, since the electrical wiring part 2 connecting the optoelectronic component (E0) and the first component (E1) is no longer required, the connection between the optoelectronic component (E0) and the first component (E1) can be shortened. Since the connection between the optoelectronic component (E0) and the first component (E1) can be shortened, it is thought that connection loss between the optoelectronic component (E0) and the first component (E1) can be suppressed.

Similarly, in the wiring substrate 1 of the present embodiment, the second component mounting region (A2) is provided on the component mounting surface (1a) so as to at least partially overlap with the first component mounting region (A1), which is within the range in which the recess 20 is formed. When the second component mounting region (A2) is provided so as to at least partially overlap with the first component mounting region (A1), the second component (E2) (see FIG. 2) and the first component (E1) (see FIG. 2) are connected, which may result in a less complex structure, easier alignment, and easier connection. When the second component (E2) and the first component (E1) are directly connected, since the electrical wiring part 2 connecting the second component (E2) and the first component (E1) is no longer required, the connection between the second component (E2) and the first component (E1) can be shortened. Since the connection between the second component (E2) and the first component (E1) can be shortened, it is thought that connection loss between the second component (E2) and the first component (E1) can be suppressed.

In the example of FIG. 1, the optoelectronic component mounting region (A0) and the second component mounting region (A2) are formed adjacent to each other on the component mounting surface (1a). The term “adjacent” means that multiple regions are formed so as to be in contact with each other in a certain direction, or so as to be close to each other with a predetermined spacing without intervening another component or a region in which another component is mounted. Further, in the example of FIG. 1, the first component mounting region (A1) is formed to be adjacent to each of the optoelectronic component mounting region (A0) and the second component mounting region (A2) in a thickness direction (Z direction) of the electrical wiring part 2.

As illustrated in FIG. 1, in the wiring substrate 1 of the embodiment, the electrical wiring part 2 is not particularly limited. However, in the example of FIG. 1, the electrical wiring part 2 is a so-called build-up wiring substrate. Specifically, the electrical wiring part 2 includes: a core substrate 21 that has a first surface (21a) and a second surface (21b) facing each other in the thickness direction; an insulating layer 221, a conductor layer 231, an insulating layer 222, and a conductor layer 232 that are sequentially laminated on the first surface (21a) of the core substrate 21; and an insulating layer 223, a conductor layer 233, an insulating layer 224, and a conductor layer 234 that are sequentially laminated on the second surface (21b) of the core substrate 21. In each of the insulating layers (221-224), via conductors 25 connecting the conductor layers sandwiching the each of the insulating layers (221-224) are formed. A laminated structure of the electrical wiring part, and the number of conductor layers and the number of insulating layers included in the electrical wiring part are not limited to the laminated structure of the electrical wiring part 2 in the example of FIG. 1, and the number of conductor layers (231-234) and the number of insulating layers (221-224) included in the electrical wiring part 2. The electrical wiring part 2 may be, for example, a so-called double-sided wiring substrate constituted only by the core substrate 21.

In the example of FIG. 1, the core substrate 21 includes an insulating layer 213 and conductor layers 212 that are respectively formed on both sides of the insulating layer 213. In the insulating layer 213, through-hole conductors 211 that penetrate the insulating layer 213 and connect the conductor layers 212 on both sides are provided. Inner sides of the tubular through-hole conductors 211 are filled with, for example, a filler 214 formed of an insulating resin such as an epoxy resin, or a conductive resin containing metal particles.

In the example of FIG. 1, the electrical wiring part 2 further includes a solder resist 241 formed on the first surface (21a) side of the core substrate 21 and a solder resist 242 formed on the second surface (21b) side of the core substrate 21. One surface (1a) of the electrical wiring part 2 (the first surface of the wiring substrate 1) is mainly constituted by an upper surface of the solder resist 241, and the other surface (1b) of the electrical wiring part 2 (the second surface of the wiring substrate 1) is mainly constituted by an upper surface of the solder resist 242. In the wiring substrate 1 of the embodiment, the one surface of the electrical wiring part 2 constitutes the component mounting surface (1a) of the wiring substrate 1. The solder resist 241 partially covers each of the insulating layer 222 and the conductor layer 232, and the solder resist 242 partially covers each of the insulating layer 224 and the conductor layer 234. The solder resist 241 has openings (241a) that each expose a portion of the conductor layer 232. Similarly, the solder resist 242 also has openings (242a) that each expose a portion of the conductor layer 234.

The insulating layers (221, 224) and the insulating layer 213 can be formed, for example, using a thermosetting insulating resin such as an epoxy resin, a bismaleimide triazine resin (BT resin), or a phenol resin. The insulating layers (221, 224) and the insulating layer 213 may also be formed using a thermoplastic insulating resin such as a fluororesin, a liquid crystal polymer (LCP), a fluorinated ethylene (PTFE) resin, a polyester (PE) resin, or a modified polyimide (MPI) resin. Although not illustrated, the insulating layers each may contain a core material (reinforcing material) formed of a glass fiber, an aramid fiber, or the like, and each may contain an inorganic filler formed of fine particles of silica (SiO₂), alumina, mullite, or the like. On the other hand, the solder resists (241, 242) are formed of, for example, a photosensitive epoxy resin, a photosensitive polyimide resin, or the like.

The conductor layers (231-234) and conductor layers 212, the through-hole conductors 211, and the via conductors 25 can be formed using any metal such as copper or nickel. In FIG. 1, these conductor layers or conductors are simplified and depicted as each having a one-layer structure. However, these conductor layers or conductors may each have a multilayer structure including two or more films. For example, the conductor layers (231-234) and conductor layers 212 may each have a two-layer structure including an electroless plating film and an electrolytic plating film.

The conductor layers (231-234) and conductor layers 212 may each include any conductor patterns. In the example of FIG. 1, the conductor layer 232 includes optoelectronic component conductor pads 2321 formed in the optoelectronic component mounting region (A0) of the component mounting surface (1a) and second component conductor pads 2322 formed in the second component mounting region (A2) of the component mounting surface (1a). The optoelectronic component conductor pads 2321 are formed at positions corresponding to electrodes (E02) of the optoelectronic component (E0) connected to the wiring substrate 1 (electrodes (E02) of the optoelectronic component (E0) included in the optoelectronic component mounting region (A0) that does not overlap with the first component mounting region (A1), see FIG. 2). The second component conductor pads 2322 are formed at positions corresponding to electrodes (E22) of the second component (E2) connected to the wiring substrate 1 (electrodes (E22) of the second component (E2) included in the second component mounting region (A2) that does not overlap with the first component mounting region (A1), see FIG. 2). Further, in the example of FIG. 1, the conductor layer 212 includes first component conductor pads 2121 formed in the first component mounting region (A1). The first component conductor pads 2121 are formed in shapes and sizes that allow the mounting of the first component (E1) on the wiring substrate 1.

In the example of FIG. 1, the electrical wiring part 2 further includes optoelectronic component conductive connecting members 261 and second component conductive connecting members 262 in the openings (241a) of the solder resist 241. The optoelectronic component conductive connecting members 261 are structured to allow connection between the electrodes (E02) (see FIG. 2) of the optoelectronic component (E0) and the optoelectronic component conductor pads 2321. The second component conductive connecting members 262 are structured to allow connection between the electrodes (E22) (see FIG. 2) of the second component (E2) and the second component conductor pads 2322. The optoelectronic component conductive connecting members 261 and the second component conductive connecting members 262 are, for example, conductor posts, and are formed, for example, using any metal, such as copper or nickel. When necessary, a conductive connector is formed on each of the optoelectronic component conductive connecting members 261 and second component conductive connecting members 262, using solder such as tin-based solder or gold-based solder. The optoelectronic component conductive connecting members 261 and the second component conductive connecting members 262 are, for example, conductive bumps, and may be formed, for example, using solder such as tin-based solder or gold-based solder. When the optoelectronic component conductive connecting members 261 and the second component conductive connecting members 262 are used, it may be possible that the mounting of the optoelectronic component (E0) and the second component (E2) is facilitated, and a short circuit between the optoelectronic component conductor pads 2321 or between the second component conductor pads 2322 is prevented.

As illustrated in FIG. 1, the optical wiring part 3 is structured to be optically connectable to the optoelectronic component (E) (see FIG. 2) to be mounted on the wiring substrate 1. In the example of FIG. 1, the optical wiring part 3 is structured to be optically connectable to the optoelectronic component (E0) at one end in a light propagation direction (+X direction or −X direction, hereinafter also simply referred to as the “X direction”), and connectable to an optical fiber (F) via a connector (C) at the other end. It is also possible that the optical wiring part 3 is mounted in the optical wiring mounting region (AL) on the component mounting surface (1a) of the electrical wiring part 2 using a support member 4.

As illustrated in FIG. 1, the optical wiring part 3 includes an optical wiring 31. The optical wiring part 3 may also include a support substrate 32 used as a base for forming the optical wiring 31. When the optical wiring part 3 includes the support substrate 32, the optical wiring part 3 may have improved resistance to thermal contraction caused by temperature changes. In the example of FIG. 1, the support substrate 32 is formed on the optical wiring 31 on the opposite side with respect to the component mounting surface (1a). It is also possible that the support substrate 32 is formed on the component mounting surface (1a) side of the optical wiring 31. Further, it is also possible that the optical wiring part 3 is formed on the wiring substrate 1 without using the support substrate 32. In this case, the optical wiring part 3 may be formed on the wiring substrate 1, or a preformed optical wiring part 3 may be placed using an adhesive material.

In the example of FIG. 1, the optical wiring 31 includes a core part 311 capable of propagating an optical signal, and a cladding part 312 surrounding the core part 311. The cladding part 312 is provided around the core part 311, and sandwiches the core part 311 in any direction perpendicular to an extension direction of the core part 311, that is, an optical signal propagation direction in the core part 311 (the X direction). In the example of FIG. 1, the cladding part 312 includes a first cladding 3121, which forms a portion on a side of the core part 311 farther from the electrical wiring part 2 (a portion above the core part 311), and a second cladding 3122, which forms a portion on a side of the core part 311 closer to the electrical wiring part 2 (a portion below the core part 311). The first cladding 3121 covers an upper surface of the core part 311, and the second cladding 3122 covers a lower surface of the core part 311. The first cladding 3121 and/or the second cladding 3122 may cover side surfaces of the core part 311 (a surface facing the +Y direction and a surface facing the −Y direction (the opposite direction with respect to the +Y direction, not illustrated in FIG. 1)).

The core part 311 and the cladding part 312 are each formed using a material having an appropriate refractive index. The core part 311 and the cladding part 312 may be formed of, for example, an organic material (organic substance), an inorganic material (inorganic substance), or a hybrid material, such as an inorganic polymer, containing an organic component and an inorganic component. Examples of inorganic materials include quartz glass, silicon, and the like, and examples of organic materials include acrylic resins such as polymethylmethacrylate (PMMA), polyimide resins, polyamide resins, polyether resins, epoxy resins, and the like. An optical wiring part 3 formed of an organic substance tends to be lightweight and highly flexible. Further, an optical wiring part 3 formed of an inorganic material tends to have low optical loss and high weather resistance.

The core part 311 and the cladding part 312 may be formed of different materials, or may be formed of materials of the same type. The core part 311 is formed of a material having a higher refractive index than a material used for the cladding part 312 so that total reflection of light is possible at an interface between the core part 311 and the cladding part 312. It is also possible that the core part 311 and the cladding part 312 are formed of materials having the same refractive index, and then the refractive indexes of the core part 311 and the cladding part 312 are made different from each other by appropriate processing.

The optical wiring 31 may be formed using any method. In the example of FIG. 1, the optical wiring 31 is formed on one main surface of the support substrate 32. The support substrate 32 may be removed after the optical wiring 31 is formed. That is, the optical wiring part 3 may be disposed on the wiring substrate 1 without including the support substrate 32. Further, the optical wiring 31 and the support substrate 32 may be bonded to each other by curing the material of the cladding part 312 in a semi-cured state on the support substrate 32. Further, the optical wiring 31 may be formed separately from the support substrate 32 and fixed to the support substrate 32, for example, with any adhesive (not illustrated). The optical wiring part 3 may be formed directly on the wiring substrate 1.

The support substrate 32 has, for example, a thermal expansion coefficient lower than that of the optical wiring 31. When the core part 311 and the cladding part 312 have different thermal expansion coefficients, the support substrate 32 has, for example, a thermal expansion coefficient lower than an average value of the thermal expansion coefficients of the core part 311 and the cladding part 312. Preferably, the thermal expansion coefficient of the support substrate 32 is lower than the lower of the thermal expansion coefficients of the core part 311 and the cladding part 312. In this way, the support substrate 32 may be formed of any material so as to have a thermal expansion coefficient lower than that of the optical wiring 31 and preferably have a rigidity higher than that of the optical wiring 31. For example, the support substrate 32 may have a bending rigidity higher than that of the optical wiring 31. Examples of the material of the support substrate 32 include: glasses such as soda-lime glass, borosilicate glass, and quartz glass; various ceramics such as alumina, silicon nitride, and silicon oxide; and semiconductors such as silicon and germanium.

The thermal expansion coefficient of the optical wiring 31 is, for example, 10 ppm/°C-100 ppm/°C. In contrast, the thermal expansion coefficient of the support substrate 32 is, for example, 3 ppm/°C-10 ppm/°C. The bending rigidity of the support substrate 32 is, for example, 1.1 or more times the bending rigidity of the optical wiring 31, and 2 or less times the bending rigidity of the electrical wiring part 2. It is thought that the optical wiring 31 can be easily handled and held. Further, it is also thought that the optical wiring 31 can follow the warping of the electrical wiring part 2 to some extent. A thickness of the support substrate 32 is not particularly limited, but is desirably set to, for example, about 30 μm or more and 1000 μm or less.

As illustrated in FIG. 1, the support member 4 may be formed on the component mounting surface (1a) of the wiring substrate 1 (the upper surface of the solder resist 241 of the electrical wiring part 2). In the example of FIG. 1, the support member 4 is formed in the optical wiring mounting region (AL) on the component mounting surface (1a). The support member 4 may be formed on the component mounting surface (1a) so as to span across the optoelectronic component mounting region (A0) and the optical wiring mounting region (AL).

The support member 4 is not particularly limited, but may be, for example, a film, a coating film, or the like. When a film is used, a surface of the support member 4 facing the electrical wiring part 2 side may have adhesiveness so that it can be fixed to the electrical wiring part 2. When a film is used, a surface of the support member 4 facing the optical wiring part 3 side may have adhesiveness so that it can be fixed to the optical wiring part 3.

A material forming the support member 4 is not particularly limited, but is a resin material, a metal material, an inorganic material, or a composite of these materials. A resin material is preferably used as the material forming the support member 4. Examples of the resin material forming the support member 4 include thermosetting resins, thermoplastic resins, UV-curable resins, and the like. Further, these resins may each be independently used, or two or more of these resins may be used in combination. Examples of combinations of multiple resins include a combination of a thermosetting resin and a UV-curable resin, a combination of a thermosetting resin and a thermoplastic resin, and the like. When the material forming the support member 4 is a resin material, a glass transition temperature thereof is preferably 50 °C-200 °C. A thermal expansion coefficient of the support member 4 is, for example, 30 ppm/°C-200 ppm/°C. A thickness of the support member 4 is not particularly limited, but is about 5 μm or more and 200 μm or less.

The support member 4 may contain particles such as inorganic particles, metal particles, or resin particles. Sizes of the particles contained in the support member 4 are not particularly limited, but are, for example, about 0.1 μm or more and 20 μm or less. By containing particles in the support member 4, the rigidity and heat resistance of the support member 4 are improved.

A metal material forming the support member 4 is not particularly limited, but examples thereof include copper, aluminum, nickel, titanium, beryllium, iron, platinum, stainless steel, and the like. The support member 4 may be formed by covering a metal material serving as a core material with a resin material, or may be formed of two or more layers including a layer formed of a metal material and a layer formed of a resin material having adhesiveness to the metal material. By using a metal material, a heat dissipation property is imparted to the support member 4.

An inorganic material forming the support member 4 is not particularly limited, but examples thereof include glass, semiconductor materials, and the like. The support member 4 may be formed by covering an inorganic material serving as a core material with a resin material, or may be formed of two or more layers including a layer formed of an inorganic material and a layer formed of a resin material having adhesiveness to the inorganic material. By using an inorganic material, rigidity and thermal expansion resistance are imparted to the support member 4.

As illustrated in FIG. 2, in the present embodiment, the wiring substrate 1 in a state in which the first component (E1) is mounted in the first component mounting region (A1) is referred to as a component-mounted wiring substrate 10. A wiring substrate 1 in a state in which the first component (E1) is mounted in the first component mounting region (A1) and the optoelectronic component (E0) is mounted in the optoelectronic component mounting region (A0) may be referred to as a component-mounted wiring substrate 10, or a wiring substrate 1 in a state which the first component (E1) is mounted in the first component mounting region (A1), the second component (E2) is mounted in the second component mounting region (A2), and the optoelectronic component (E0) is mounted in the optoelectronic component mounting region (A0) may be referred to as a component-mounted wiring substrate 10. That is, a wiring substrate 1 in a state in which any component including the first component (E1) is mounted in a predetermined mounting region may be referred to as a component-mounted wiring substrate 10. It is desirable that an upper surface of the first component (E1) is flush with or positioned above an upper surface of the insulating layer 222 of the wiring substrate 1 (see FIG. 2).

The optoelectronic component (E0), the first component (E1), and the second component (E2) are separate components with different specifications and intended uses. Here, “separate components” means that the optoelectronic component (E0), the first component (E1), and the second component (E2) are distinct components, and does not necessarily mean that they are of different types. For example, the first component (E1) and the second component (E2) may be of the same type, or may be components having different functions from each other.

The first component (E1) illustrated in FIG. 2 is, for example, an electronic component that converts a format of an electrical signal between an input signal to the first component (E1) and an output signal from the first component (E1). Specifically, it converts an analog signal to a digital signal, and converts a digital signal to an analog signal. When the optoelectronic component (E0) is a light receiving element, the first component (E1) is, for example, an AD converter that converts an analog signal, which is an input signal from the optoelectronic component (E0), into a digital signal and outputs the converted digital signal to the first component (E1). When the optoelectronic component (E0) is a light emitting element, the first component (E1) is, for example, a DA converter that converts a digital signal, which is an input signal from the second component (E2), into an analog signal and outputs the converted analog signal to the optoelectronic component (E0). The first component (E1) may be an amplifier that adjusts a current/voltage level of an input signal from the second component (E2) and outputs it to the optoelectronic component (E0) and/or adjusts a current/voltage level of an input signal from the optoelectronic component (E0) and outputs it to the second component (E2).

An output signal from the first component (E1) to the optoelectronic component (E0) or an input signal from the optoelectronic component (E) to the first component (E1) may be a digital signal. Further, an input signal from the second component (E2) to the first component (E1) or an output signal from the first component (E1) to the second component (E2) may be an analog signal. For example, the first component (E1) is embodied as a DC-AC converter, an AC-DC converter, an AC-AC converter, a DC-DC converter, a preamplifier, a postamplifier, or the like.

As illustrated in FIG. 2, the first component (E1) has the electrodes (E11, E12) formed thereon. The first component (E1) has first component conductive connecting members (E11a, E12a) formed on the electrodes (E11, E12). In the example of FIG. 2, the first component (E1) is mounted in the first component mounting region (A1) in the recess 20 of the wiring substrate 1 by so-called face-up mounting. The first component conductive connecting members (E11a) are structured to allow connection between the electrodes (E01) of the optoelectronic component (E0) and the electrodes (E11). The first component conductive connecting members (E12a) are structured to allow connection between the electrodes (E21) of the second component (E2) and the electrodes (E12). The first component conductive connecting members (E11a, E12a) may be formed of any of conductor posts, conductive connectors, and conductive bumps. The first component conductive connecting members (E11a, E12a) are conductive posts and are formed, for example, using any metal, such as copper, nickel, gold, silver, or palladium.

The conductive connectors of the first component conductive connecting members (E11a, E12a) may be formed using metals such as tin, copper, nickel, gold, and silver.

The first component conductive connecting members (E11a, E12a) are conductive bumps, and may be formed, for example, using solder such as tin-based solder or gold-based solder. When the first component conductive connecting members (E11a, E12a) are used, the mounting of the optoelectronic component (E0) and the second component (E2) is facilitated. Further, the first component conductive connecting members (E11a, E12a) may also prevent a short circuit between the electrodes (E11, E12) of the first component (E1). The electrode surface of the first component (E1) corresponds to the upper surface of the first component (E1) in the example of FIG. 2, and the non-electrode surface of the first component (E1) corresponds to the lower surface of the first component (E1) in the example of FIG. 2.

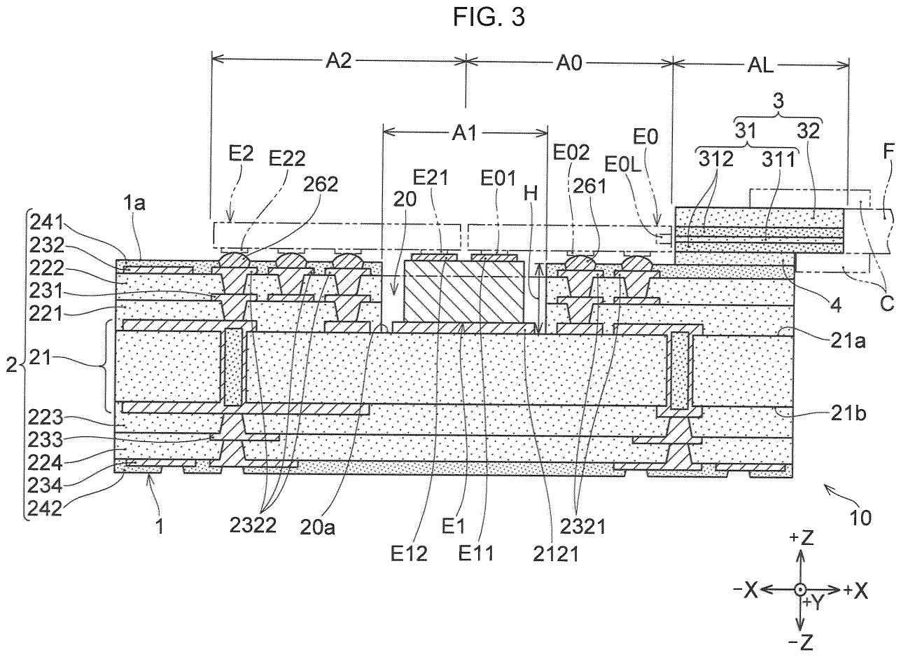

As illustrated in FIG. 3, the first component (E1) may be connected to the optoelectronic component (E0) and the second component (E2) by metal bonds that directly bond metals of the electrodes (E11, E12) of the first component (E1) with metals of the electrodes (E01) of the optoelectronic component (E0) and metals of the electrodes (E21) of the second component (E2). That is, the metals of the electrodes (E11, E12) of the first component (E1) are each formed of a metal capable of metal bonding. When the first component (E1) is bonded to the optoelectronic component (E) and the second component (E2) by metal bonding, the metals of the electrodes (E11, E12) of the first component (E1), as well as the metals of the electrode (E01) of the optoelectronic component (E0) and the metals of the electrode (E21) of the second component (E2) are each a metal capable of metal bonding and are each formed of, for example, copper, gold, silver, palladium, and the like. As an example, the electrodes (E11, E12) of the first component (E1) are formed of copper, the electrodes (E01) of the optoelectronic component (E0) and the electrodes (E21) of the second component (E2) are formed of copper, and the electrodes (E11, E12) of the first component (E1) are bonded to the electrodes (E01) of the optoelectronic component (E0) and the electrodes (E21) of the second component (E2) by the same metal bonding (for example, copper-copper bonding). The electrodes (E11, E12) of the first component (E1), the electrodes (E01) of the optoelectronic component (E0), and the electrodes (E21) of the second component (E2) may be formed of the same metal or different metals. Further, the electrodes (E11, E12) of the first component (E1), the electrodes (E01) of the optoelectronic component (E0), and the electrodes (E21) of the second component (E2) may be formed with the same thickness or with different thicknesses.

As illustrated in FIG. 2, the recess 20 provided in the first component mounting region (A1) has a lower surface (20a) in the recess 20 and has an upper surface at the same position as the component mounting surface (1a). A height (H) from the lower surface (20a) to the upper surface is set to a height that allows the first component (E1) to be connected to the optoelectronic component (E0) using the first component conductive connecting members (E11a, E12a) formed on the electrodes (E11, E12) of the first component (E1). Further, the height (H) is set to a height that allows the first component (E1) to be connected to the second component (E2). In the wiring substrate 1 in the example of FIG. 1, the lower surface (20a) of the recess 20 is formed by the first surface (21a) of the core substrate 21. The lower surface (20a) of the recess 20 may be formed on the upper surface of the insulating layer 221, at a position between the upper and lower surfaces of the insulating layer 221, or at a position between the upper and lower surfaces of the insulating layer 222, or may be formed at a position further recessed from the first surface (21a) of the core substrate 21.

For example, an uppermost part of each of the first component conductive connecting members (E11a) (position in the Z direction) is adjusted to be in substantially the same plane as an uppermost part of each of the optoelectronic component conductive connecting members 261 (position in the Z direction). It is thought that, by forming the uppermost parts of the first component conductive connecting members (E11a) and the optoelectronic component conductive connecting members 261 in substantially the same plane, the optoelectronic component (E0) does not tilt when mounted on the wiring substrate 1, making the connection between the optoelectronic component (E0) and the first component (E1) and the connection between the optoelectronic component (E0) and the wiring substrate 1 easier and more reliable. Further, for example, an uppermost part of each of the first component conductive connecting members (E12a) (position in the Z direction) is adjusted to be in substantially the same plane as an uppermost part of each of the second component conductive connecting members 262 (position in the Z direction).

It is thought that, by forming the uppermost parts of the first component conductive connecting members (E12a) and the second component conductive connecting members 262 in substantially the same plane, the second component (E2) does not tilt when mounted on the wiring substrate 1, making the connection between the second component (E2) and the first component (E1) and the connection between the second component (E2) and the wiring substrate 1 easier and more reliable.

The optoelectronic component (E0) illustrated in FIG. 2 is, for example, an electrical component including a light receiving element and/or a light emitting element having a photoelectric conversion function. For example, the optoelectronic component (E0) is embodied as a light receiving element such as a photodiode, and a light emitting element such as a light emitting diode (LED), an organic light emitting diode (OLED), a laser diode (LD), and a vertical-cavity surface emitting laser (VCSEL).

As illustrated in FIG. 2, the optoelectronic component (E0) has the electrodes (E01, E02) and a light receiving/emitting part (E0L) formed thereon. In the example of FIG. 2, the optoelectronic component (E0) is mounted in the optoelectronic component mounting region (A0) of the wiring substrate 1 by so-called face-down mounting (flip-chip mounting). When the optoelectronic component (E0) is mounted in the optoelectronic component mounting region (A0), the electrodes (E02) are connected to the optoelectronic component conductor pads 2321 of the electrical wiring part 2 by the optoelectronic component conductive connecting members 261, and the electrodes (E01) are connected to the electrodes (E11) of the first component (E1) by the first component conductive connecting members (E11a) formed on the electrodes (E11) of the first component (E1). Further, the light receiving/emitting part (E0L) is formed at a position facing the core part 311 of the optical wiring 31. In the example of FIG. 2, the electrode surface of the optoelectronic component (E0) corresponds to the lower surface of the optoelectronic component (E0), and the non-electrode surface of the optoelectronic component (E0) corresponds to the upper surface of the optoelectronic component (E0).

Between the optoelectronic component (E0) and the optical wiring part 3, it may be possible that a resin such as a filling resin is not formed, or an optical resin is formed. The optical resin is a transparent resin, a resin with an adjusted refractive index, or both. A material of the optical resin is not particularly limited, but examples thereof include an epoxy resin, a silicone resin, an acrylic resin, and the like. By forming an optical resin between the optoelectronic component (E0) and the optical wiring part 3, optical transmission between the light receiving/emitting part (E0L) of the optoelectronic component (E0) and the optical wiring part 3 can be easily realized.

When the optoelectronic component (E0) is a light receiving element, an optical signal enters the core part 311 of the optical wiring 31 from an external source such as an optical fiber (F). After that, the optical signal that has entered from the core part 311 of the optical wiring 31 is incident on the light receiving/emitting part (E0L), where it is converted into an electrical signal based on the optical signal incident on the light receiving/emitting part (E0L), which functions as a light receiving part, and the electrical signal is output from the electrodes (E01). The electrical signal output from the electrodes (E01) is input to the first component (E1). When the optoelectronic component (E0) is a light emitting element, the optoelectronic component (E0) converts an electrical signal input to the electrodes (E01) from the first component (E1) to an optical signal, and emits the optical signal from the light receiving/emitting part (E0L), which functions as a light emitting part. The optical signal emitted from the light receiving/emitting part (E0L) is incident on the core part 311 of the optical wiring 31. Further, the optical signal propagated through the core part 311 is incident on the optical fiber (F). For example, an electrical signal input to or output from the electrodes (E01) is an analog electrical signal, and light emitted from or incident on the light receiving/emitting part (E0L) is an analog optical signal. Light emitted from the light receiving/emitting part (E0L) or incident on the light receiving/emitting part (E0L) may be a digital optical signal. Further, an electrical signal input to or output from the electrodes (E01) may be a digital electrical signal.

The second component (E2) illustrated in FIG. 2 is, for example, an electronic component, such as a semiconductor device, that performs conversion of an electrical signal for causing the optoelectronic component (E0) to emit light, and/or processing of an electrical signal converted by the optoelectronic component (E0). When the optoelectronic component (E0) is a light emitting element, the second component (E2) is, for example, an arithmetic device that performs a predetermined operation with respect to a digital signal, which is an input signal to the second component (E2), and outputs the processed digital signal to the first component (E1). When the optoelectronic component (E0) is a light receiving element, the second component (E2) is, for example, an arithmetic device that performs a predetermined operation with respect to a digital signal, which is an input signal from the first component (E1), and outputs the processed digital signal to the conductor layer 232 included in the wiring substrate 1. For example, the second component (E2) is embodied as a driver IC, a microcontroller, a programmable logic device (PLD), or the like.

As illustrated in FIG. 2, the second component (E2) has the electrodes (E21, E22) formed thereon. In the example of FIG. 2, the second component (E2) is mounted in the second component mounting region (A2) of the wiring substrate 1 by so-called face-down mounting (flip-chip mounting). When the second component (E2) is mounted in the second component mounting region (A2), the electrodes (E22) are connected to the second component conductor pads 2322 of the electrical wiring part 2 by the second component conductive connecting members 262, and the electrodes (E21) are connected to the electrodes (E12) of the first component (E1) by the first component conductive connecting members (E12a) formed on the electrodes (E12) of the first component (E1). In the example of FIG. 2, the electrode surface of the second component (E2) corresponds to the lower surface of the second component (E2), and the non-electrode surface of the second component (E2) corresponds to the upper surface of the second component (E2).

In the component-mounted wiring substrate 10 of the present embodiment, the first component (E1) is mounted by face-up mounting in the first component mounting region (A1) inside the recess 20 of the wiring substrate 1, so as to enable connection between the optoelectronic component (E0) and the first component (E1). When the first component (E1) is mounted face-up, by mounting the optoelectronic component (E0) face-down so that the electrodes (E01) of the optoelectronic component (E0) and the electrodes (E11) of the first component (E1) face each other, the optoelectronic component (E0) can be directly connected to the first component (E1) without going through the electrical wiring part 2. When directly connecting the optoelectronic component (E0) and the first component (E1), a connection structure between the optoelectronic component (E0) and the first component (E1) becomes less complex and is simplified. As a result, it is thought that process conditions and alignment for the connection also are simplified, a connection distance between the first component (E1) and the optoelectronic component (E0) is shortened, and connection loss is suppressed.

When the first component (E1) has the first component conductive connecting members (E11a) on the electrodes (E11), it may be possible that the first component (E1) and the optoelectronic component (E0) included in the component-mounted wiring substrate 10 can be easily connected. Further, when the first component conductive connecting members (E11a) are used, a connection length between the optoelectronic component (E0) and the first component (E1) can be made as short as possible. When the connection length between the optoelectronic component (E0) and the first component (E1) is shortened, it is thought that the connection loss between the optoelectronic component (E0) and the first component (E1) can be suppressed.

Similarly, when the first component (E1) is mounted face-up, by mounting the second component (E2) face-down so that the electrodes (E21) of the second component (E2) and the electrodes (E12) of the first component (E1) face each other, the second component (E2) can be directly connected to the first component (E1) without going through the electrical wiring part 2. When directly connecting the second component (E2) and the first component (E1), a connection structure between the second component (E2) and the first component (E1) becomes less complex and is simplified. As a result, it is thought that process conditions and alignment for the connection also are simplified, a connection distance between the second component (E2) and the first component (E1) is shortened, and connection loss is suppressed.

When the first component (E1) has the first component conductive connecting members (E12a) on the electrodes (E12), the first component (E1) and the second component (E2) included in the component-mounted wiring substrate 10 can be easily connected. Further, when the first component conductive connecting members (E12a) are used, a connection length between the second component (E2) and the first component (E1) can be made as short as possible. When the connection length between the second component (E2) and the first component (E1) is shortened, it is thought that the connection loss between the second component (E2) and the first component (E1) can be suppressed.

In one example, the first component conductive connecting members (E12a) are conductive posts, while the optoelectronic component conductive connecting members 261 and the second component conductive connecting members 262 are conductive posts or solder bumps. It is also possible that the first component conductive connecting members (E12a) are solder bumps, while the optoelectronic component conductive connecting members 261 and the second component conductive connecting members 262 are conductive posts or solder bumps. Further, it is also possible that, without providing the first component conductive connecting members (E12a), metal of the electrodes (E11, E12) of the first component (E1), metal of the electrodes (E01) of the optoelectronic component (E0), and metal of the electrodes (E21) of the second component (E2) are metal-bonded, and the optoelectronic component conductive connecting members 261 and the second component conductive connecting members 262 are conductive posts or solder bumps. A melting point of the first component conductive connecting members (E12a), a melting point of the optoelectronic component conductive connecting members 261, and a melting point of the second component conductive connecting members 262 may be substantially the same temperature, or there may be a temperature difference of 5 °C or more.

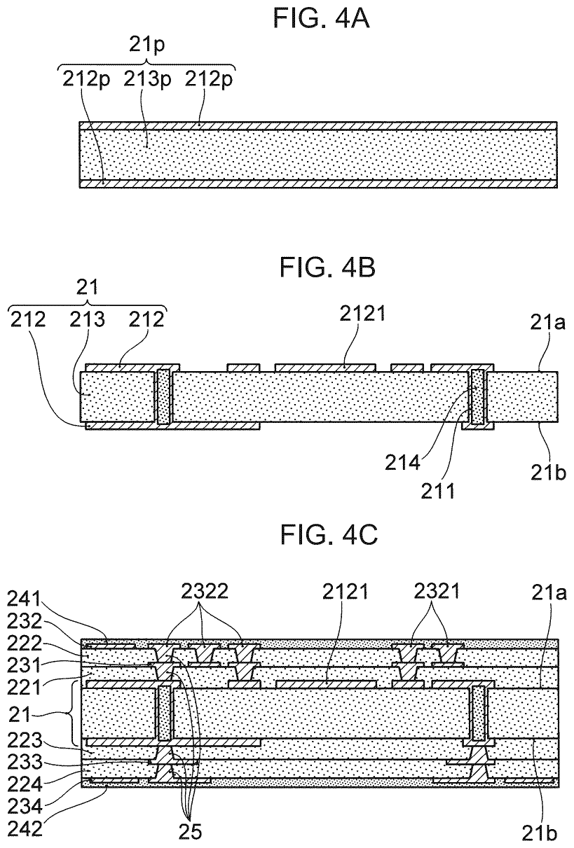

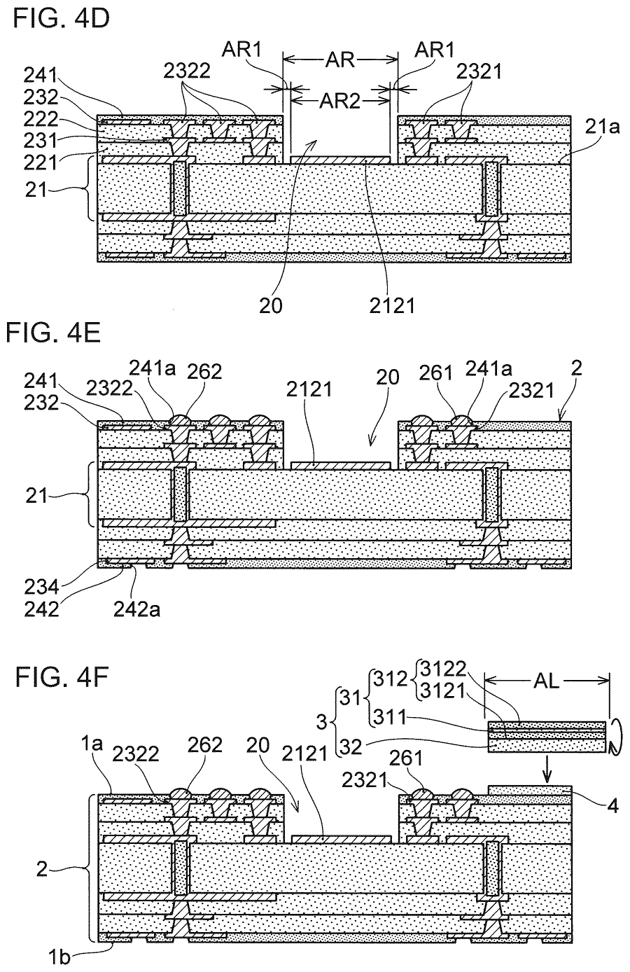

Next, as an example of a method for manufacturing a wiring substrate of the present embodiment, the wiring substrate 1 illustrated in FIG. 1 is manufactured using a method for manufacturing a wiring substrate, described with reference to FIGS. 4A to 4F. Unless there is a description different from the description provided above regarding the materials of the structural elements of the wiring substrate 1, the structural elements may be formed using any of the materials described above with respect to the structural elements.

First, the electrical wiring part 2 is prepared. An example of a method for manufacturing the electrical wiring part 2 is illustrated in FIGS. 4A to 4E. In the example of FIGS. 4A to 4E, the manufacturing of the electrical wiring part 2 may be performed using a general method for forming a build-up wiring substrate that includes a core substrate.

First, as illustrated in FIG. 4A, a double-sided copper-clad substrate (21p) is prepared, which includes a plate-shaped insulator (213p) with copper foil (212p) formed on both sides of the insulator (213p).

Next, as illustrated in FIG. 4B, the core substrate 21 is formed using the double-sided copper-clad substrate (21p). Through holes are formed in the double-sided copper-clad substrate (21p), for example, by drilling or laser processing. After that, the through-hole conductors 211 are formed in the through holes of the double-sided copper-clad substrate (21p) by metal coating inner walls of the through holes by electroless plating and electrolytic plating. Next, the filler 214 is formed, for example, by injecting an insulating resin, such as an epoxy resin, into cavities of the through-hole conductors 211 and solidifying the insulating resin. It is also possible that the filler 214 is formed by filling the cavities with plating or conductive paste. It is desirable that the filler 214 is flush with the copper foil (212p) of the double-sided copper-clad substrate (21p). Next, a metal coating is formed by electroless plating and electrolytic plating on the surfaces of the double-sided copper-clad substrate (21p) having the filler 214 and copper foil (212p), and the conductor layers 212 including the first component conductor pads 2121 are formed by patterning using a subtractive method. Through these formation processes, the core substrate 21 is obtained.

Next, as illustrated in FIG. 4C, the insulating layer 221 is formed on the first surface (21a) of the core substrate 21, and the insulating layer 223 is formed on the second surface (21b) of the core substrate 21. The insulating layer 221 and the insulating layer 223 are each formed, for example, by laminating a film-like insulating resin, such as an epoxy resin, onto the core substrate 21 and performing thermal compression bonding. In each insulating layer, vias (non-through holes) for forming via conductors 25 are formed, for example, by irradiation with laser, such as CO₂ laser. Next, via conductors 25 are formed in the vias of the insulating layer 221, and the conductor layer 231 is formed on the upper surface of the insulating layer 221. Similarly, via conductors 25 are formed in through holes of the insulating layer 223, and the conductor layer 233 is formed on the upper surface of the insulating layer 223. The conductor layers and the via conductors are formed, for example, using a semi-additive method or the like.

Next, using a method similar to that for forming the insulating layer 221, the insulating layer 222 is formed on the upper surfaces of the insulating layer 221 and the conductor layer 231. Similarly, using a method similar to that for forming the insulating layer 223, the insulating layer 224 is formed on the upper surfaces of the insulating layer 223 and the conductor layer 233. Next, using a method similar to that for forming the conductor layer 231, the conductor layer 232 including the optoelectronic component conductor pads 2321 and the second component conductor pads 2322 is formed on the upper surface of the insulating layer 222. Similarly, using a method similar to that for forming the conductor layer 233, the conductor layer 234 is formed on the upper surface of the insulating layer 224. Next, the solder resist 241 is formed on the upper surfaces of the insulating layer 222 and the conductor layer 232, and the solder resist 242 is formed on the upper surfaces of the insulating layer 224 and the conductor layer 234. The solder resists are each formed, for example, by applying an insulating resin such as an epoxy resin or a polyimide resin, or by attaching a film.

Next, as illustrated in FIG. 4D, the recess 20 is formed on one surface of the laminate illustrated in FIG. 4C. The formation of the recess 20 may be divided into formation of an outer region (AR1), which defines an outer edge of a formation region (AR) of the recess 20, and formation of an inner region (AR2), which is surrounded by the outer region (AR1). The outer region (AR1) is formed, for example, by mechanically cutting along an outer frame of the outer region (AR1) using a router or the like thereby removing the solder resist 241, the insulating layer 222, and the insulating layer 221 down to the first surface (21a) of the core substrate 21. It is also possible that the outer region (AR1) is formed by irradiating laser along the outer region (AR1), removing the solder resist 241, the insulating layer 222, and the insulating layer 221 down to the first surface (21a) of the core substrate 21.

After the formation of the outer region (AR1), the formation of the inner region (AR2) may be performed. The inner region (AR2) is formed, for example, by irradiating the inner region (AR2) with laser, thereby removing the solder resist 241, the insulating layer 222, and the insulating layer 221 down to the first surface (21a) of the core substrate 21. When irradiating with laser, it may be possible that the first component conductor pads 2121 reflects the laser, allowing the inner region (AR2) to be formed without damaging the core substrate 21. It is also possible that the inner region (AR2) is formed by applying an external force to peel off the solder resist 241, the insulating layer 222, and the insulating layer 221, which have become separated from surroundings, on the first component conductor pads 2121. Further, it is also possible that the inner region (AR2) is formed by mechanical cutting. When forming the outer region (AR1) and/or the inner region (AR2) by laser irradiation, it may be preferable that the conductor layers (231, 232) are not formed in the formation region (AR) of the recess 20 in order to suppress unwanted absorption of the laser.

Next, as illustrated in FIG. 4E, the openings (241a) are formed, for example, by photolithography, in the solder resists (241, 242) on the optoelectronic component conductor pads 2321 and the second component conductor pads 2322. Further, the openings (242a) are similarly formed in the solder resist 242. Next, the optoelectronic component conductive connecting members 261 and second component conductive connecting members 262 are formed by electroless plating on the optoelectronic component conductor pads 2321 and second component conductor pads 2322 exposed by the openings (241a). Through these processes, the electrical wiring part 2 is obtained. It is also possible that, after providing the openings in the solder resist and forming a protective member to protect the openings, the recess formation illustrated in FIG. 4D is performed, and then the protective member is peeled off.

After that, as illustrated in FIG. 4F, the optical wiring part 3 is prepared. First, for example, a glass plate, a ceramic plate, or a semiconductor substrate of silicon or the like, is prepared as the support substrate 32. Next, the first cladding 3121, the core part 311, and the second cladding 3122 are sequentially laminated on the surface of the support substrate 32, thereby forming the optical wiring 31. The formation of each of the first cladding 3121, the core part 311, and the second cladding 3122 is performed, for example, by coating, film compression bonding, or the like. Through these processes, the optical wiring part 3 is obtained. After the formation of the optical wiring 31, the support substrate 32 may be removed from the optical wiring part 3.

Next, the support member 4 is formed in the optical wiring mounting region (AL) on the first surface (component mounting surface) (1a) of the electrical wiring part 2. For example, the support member 4 molded into a film-like shape is formed on the component mounting surface (1a). The support member 4 is formed of, for example, any plate-like member, such as a material containing an epoxy resin and inorganic particles. The support member 4 may be fixed to the component mounting surface (1a).

Next, the optical wiring part 3 is formed on the support member 4. When being formed on the support member 4, for example, the optical wiring part 3 is flipped upside down. In other words, the optical wiring part 3 is formed on the support member 4 such that the optical wiring 31 faces the support member 4. It is also possible that the optical wiring part 3 is formed on the support member 4 without being flipped upside down, such that the support substrate 32 faces the support member 4. Further, the optical wiring part 3 may be fixed to the support member 4. Through the above processes, the wiring substrate 1 in the example of FIG. 1 is completed. It is also possible that the optical wiring 31 is formed directly on the wiring substrate without using a support substrate or a support member.

As illustrated in FIG. 1, when necessary, the connector (C) is provided to connect the optical wiring part 3 and the optical fiber (F), with the optical wiring part 3 sandwiched between an upper housing (C1) and a lower housing (C2). For example, the upper housing (C1) is attached to the support substrate 32, and the lower housing (C2) is attached to the optical wiring 31. In the process of attaching the connector (C) to the optical wiring part 3, the upper housing (C1) and the lower housing (C2) are fitted together. The connector (C) may be attached to the optical wiring part 3 before the optical wiring part 3 is formed on the component mounting surface (1a), or, as illustrated in FIG. 2, may be attached to the optical wiring part 3 after components such as the optoelectronic component (E0), the first component (E1), and the second component (E2) are mounted on the wiring substrate 1.

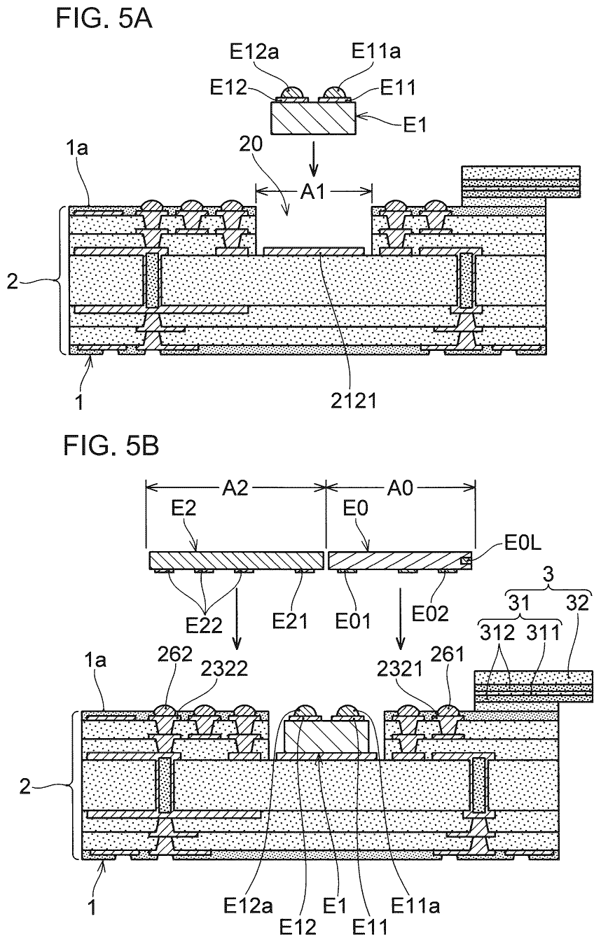

Next, as an example of a method for manufacturing the component-mounted wiring substrate of the present embodiment, the component-mounted wiring substrate 10 illustrated in FIG. 2 is manufactured using a method for manufacturing a component-mounted wiring substrate, described with reference to FIGS. 5A and 5B. Unless there is a description different from the description provided above regarding the materials of the structural elements of the component-mounted wiring substrate 10, the structural elements may be formed using any of the materials described above with respect to the structural elements.

First, as illustrated in FIG. 5A, the first component (E1) is prepared. For example, the first component (E1) is prepared in a state where the first component conductive connecting members (E11a, E12a) have already been respectively formed on the electrodes (E11, E12). The first component conductive connecting members (E11a, E12a) are formed, for example, using a metal such as electroless plating or solder. Next, the first component (E1) is mounted face-up in the first component mounting region (A1) on the first component conductor pads 2121 within the recess 20 of the wiring substrate 1, using a conductive or non-conductive adhesive or the like.

After that, as illustrated in FIG. 5B, the optoelectronic component (E0) may be mounted face-down in the optoelectronic component mounting region (A0) on the component mounting surface (1a) of the wiring substrate 1. When the optoelectronic component (E0) is mounted in the optoelectronic component mounting region (A0), the electrodes (E02) are connected to the optoelectronic component conductor pads 2321 of the electrical wiring part 2 by the optoelectronic component conductive connecting members 261, and the electrodes (E01) are connected to the electrodes (E11) of the first component (E1) by the first component conductive connecting members (E11a) formed on the electrodes (E11) of the first component (E1). Further, the light receiving/emitting part (E0L) of the optoelectronic component (E0) is formed as a position facing the core part 311 of the optical wiring 31, thereby being optically connected to the core part 311.

Furthermore, as illustrated in FIG. 5B, the second component (E2) may be mounted face-down in the second component mounting region (A2) on the component mounting surface (1a) of the wiring substrate 1. When the second component (E2) is mounted in the second component mounting region (A2), the electrodes (E22) are connected to the second component conductor pads 2322 of the electrical wiring part 2 by the second component conductive connecting members 262, and the electrodes (E21) are connected to the electrodes (E12) of the first component (E1) by the first component conductive connecting members (E12a) formed on the electrodes (E12) of the first component (E1). Through the above processes, the component-mounted wiring substrate 10 in the example of FIG. 2 is completed.

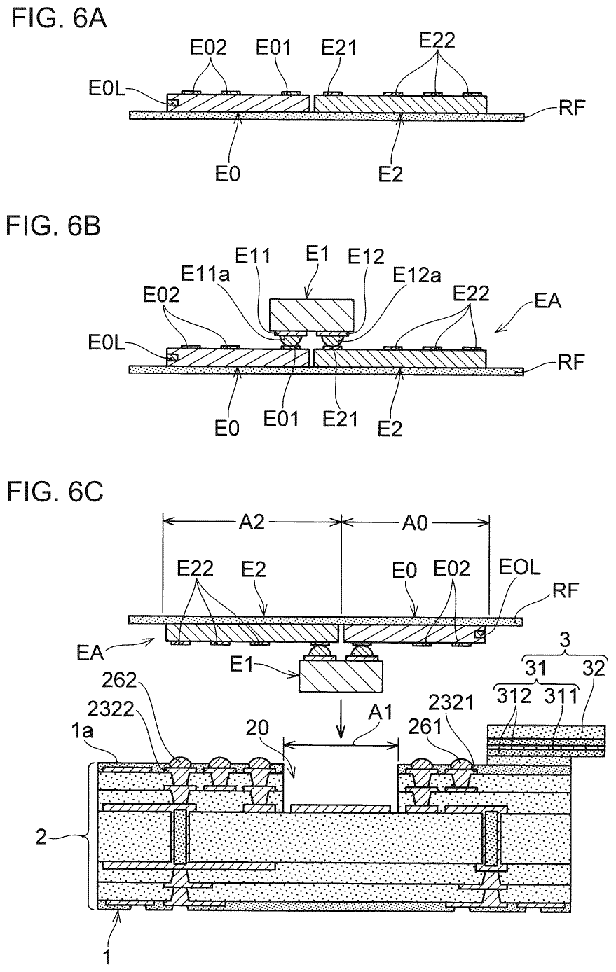

The component-mounted wiring substrate 10 illustrated in FIG. 2 may also be manufactured using a manufacturing method illustrated in FIGS. 6A to 6C.

First, as illustrated in FIG. 6A, the optoelectronic component (E0) and the second component (E2) are fixed at predetermined positions on a release film (RF). The release film (RF) has, for example, an adhesive surface, on which the optoelectronic component (E0) and the second component (E2) are fixed by an adhesive force, and is structured to allow the fixed optoelectronic component (E0) and second component (E2) to be peeled off. An example of the release film (RF) is a resin film of a polyimide resin or the like.

Next, as illustrated in FIG. 6B, the first component (E1) is mounted face-down on the optoelectronic component (E0) and the second component (E2) on the release film (RF). When the first component (E1) is mounted face-down, the electrodes (E11) of the first component (E1) are connected to the electrodes (E01) of the optoelectronic component (E0) via the first component conductive connecting members (E11a) formed on the electrodes (E11) of the first component (E1), and the electrodes (E12) of the first component (E1) are connected to the electrodes (E21) of the second component (E2) via the first component conductive connecting members (E12a) formed on the electrodes (E12) of the first component (E1) (hereinafter, the optoelectronic component (E0), the second component (E2), and the first component (E1), which are interconnected on the release film (RF) and constitute a composite component, are also referred to as a “component group (EA)”).

Next, as illustrated in FIG. 6C, the component group (EA) on the release film (RF) is mounted onto the wiring substrate 1 in a state where the component group (EA) is flipped upside down together with the release film (RF). The optoelectronic component (E0) and the second component (E2) are respectively mounted in the optoelectronic component mounting region (A0) and the second component mounting region (A2) on the component mounting surface (1a) so as to be mounted face-down on the wiring substrate 1. Further, the first component (E1) is mounted in the first component mounting region (A1) within the recess 20 so as to be mounted face-up on the wiring substrate 1. In this case, the optoelectronic component (E0) is formed at a position such that the light receiving/emitting part (E0L) faces the core part 311 of the optical wiring 31, thereby being optically connected to the core part 311, and the electrodes (E02) are connected to the optoelectronic component conductor pads 2321 of the electrical wiring part 2 via the optoelectronic component conductive connecting members 261 of the wiring substrate 1. Further, the electrodes (E22) of the second component (E2) are connected to the first component conductor pads 2322 of the electrical wiring part 2 via the second component conductive connecting members 262 of the wiring substrate 1. After the component group (EA) is mounted on the wiring substrate 1, the release film (RF) is peeled off from the component group (EA). Through the above processes, the component-mounted wiring substrate 10 in the example of FIG. 2 may be completed.

The wiring substrate and the component-mounted wiring substrate of the embodiment are not limited to those having the structures illustrated in the drawings and those having the structures, shapes, and materials exemplified in the present specification. As described above, the wiring substrate of the embodiment may include any number of conductor layers and any number of insulating layers. Wiring patterns connecting conductor pads on which components are mounted may be formed in one or more conductor layers. The optoelectronic component conductive connecting members 261 and the second component conductive connecting members 262, which are provided in the wiring substrate 1 illustrated in FIG. 1 and the like, are not necessarily provided in the wiring substrate of the embodiment. Similarly, the support member 4 and the support substrate 32 of the optical wiring part 3, which are provided in the wiring substrate 1 illustrated in FIG. 1 and the like, are also not necessarily provided in the wiring substrate of the embodiment.

In the component-mounted wiring substrate of the embodiment illustrated in FIG. 2, no filling resin such as an underfill material is formed between the optoelectronic component (E0), the first component (E1), and the second component (E2) and the wiring substrate 1 in the optoelectronic component mounting region (A0), the first component mounting region (A1), and the second component mounting region (A2). In the example of FIG. 2, a filling resin may be formed only within the recess 20 where the first component (E1) is mounted, or an optical resin may be formed instead of a filling resin, or both a filling resin and an optical resin may be formed. Further, an optical resin may be formed between mutually opposing surfaces of the optoelectronic component (E0) (specifically, the light receiving/emitting part (E0L) of the optoelectronic component (E0)) and the optical wiring part 3 (specifically, the core part 311 of the optical wiring part 3). By forming an optical resin between the optoelectronic component (E0) and the optical wiring part 3, optical transmission between the light receiving/emitting part (E0L) of the optoelectronic component (E0) and the core part 311 of the optical wiring part 3 can be easily realized.

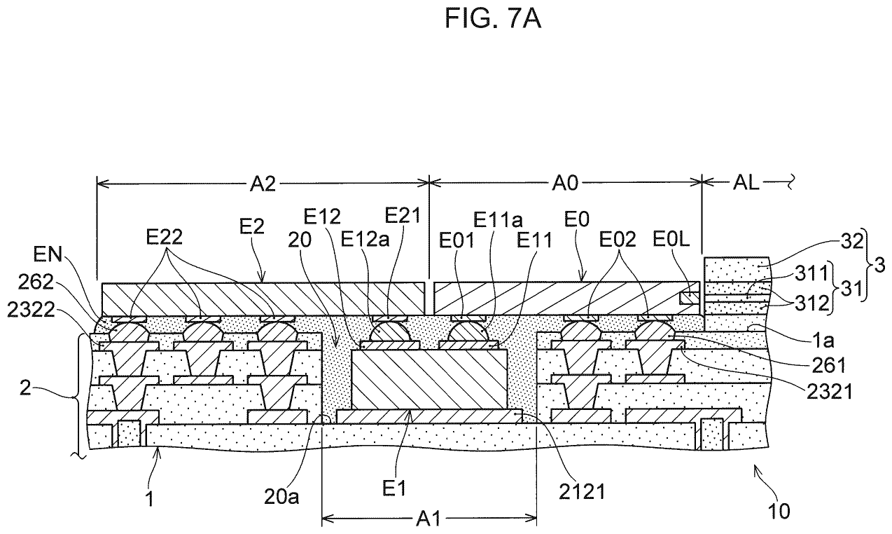

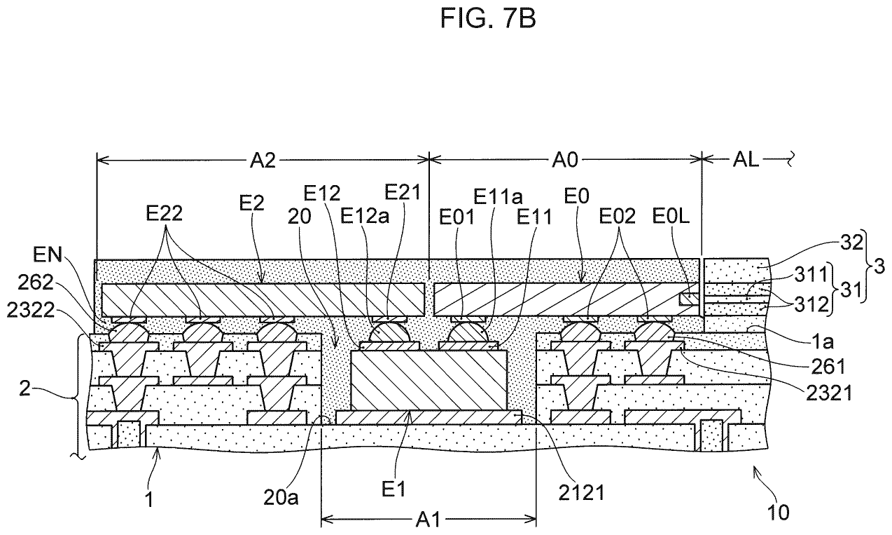

As illustrated in FIG. 7A, in the optoelectronic component mounting region (A0), the first component mounting region (A1), and the second component mounting region (A2), a filling resin (underfill material) (EN) may be formed to fill between the optoelectronic component (E0), the first component (E1), and the second component (E2) and the wiring substrate 1. In the example of FIG. 7A, the filling resin (EN) is formed to cover at least the lower surfaces of the optoelectronic component (E0) and the second component (E2), as well as the entire exposed surface of the first component (E1). Examples of the filling resin (underfill material) (EN) include resin materials such as epoxy-based resins and silicone resins. The filling resin (underfill material) (EN) may be formed from a single material or from multiple different materials. As an example, the filling resin formed within the recess 20 where the first component (E1) is mounted and the filling resin formed to cover the lower surfaces of the optoelectronic component (E0) and the second component (E2), as well as the entire exposed surface of the first component (E1), may be formed from different materials. Further, it is also possible that, between the mutually opposing surfaces of the optoelectronic component (E0) and the optical wiring part 3, no resin is formed, or an optical resin is formed. The optical resin facilitates optical transmission between the light receiving/emitting part (E0L) of the optoelectronic component (E0) and the core part 311 of the optical wiring part 3. When an optical resin is used as the filling resin (underfill material) (EN), the filling resin (underfill material) (EN) may be formed to fill between the optoelectronic component (E0), the first component (E1), and the second component (E2) and the wiring substrate 1, and further, may also be formed between the mutually opposing surfaces of the optical wiring part 3 and the optoelectronic component (E0). Examples of the optical resin include epoxy-based resins, silicone resins, acrylic resins, and the like.

As illustrated in FIG. 7B, the filling resin (EN) may be formed to cover the entire exposed surfaces of the optoelectronic component (E0), the first component (E1), and the second component (E2) and the wiring substrate 1. Examples of the filling resin (EN) include resin materials such as epoxy-based resins and silicone resins. Further, in the optoelectronic component mounting region (A0), the first component mounting region (A1), and the second component mounting region (A2), the filling resin (EN) may be formed to cover the entire exposed surfaces of the optoelectronic component (E0), the first component (E1), and the second component (E2) and the wiring substrate 1, except for the light receiving/emitting part (E0L) of the optoelectronic component (E0), leaving the light receiving/emitting part (E0L) of the optoelectronic component (E0) exposed without being covered. The filling resin (EN) may be formed from a single material or from multiple different materials. As an example, the filling resin formed within the recess 20 where the first component (E1) is mounted and the filling resin formed to cover the lower surfaces of the optoelectronic component (E0) and the second component (E2), as well as the entire exposed surface of the first component (E1), may be formed from different materials. Further, it is also possible that, between the mutually opposing surfaces of the optoelectronic component (E0) and the optical wiring part 3, no resin is formed, or an optical resin is formed. The optical resin facilitates optical transmission between the light receiving/emitting part (E0L) of the optoelectronic component (E0) and the core part 311 of the optical wiring part 3. When an optical resin is used as the filling resin (EN), the filling resin (EN) may be formed to fill the spaces between the optoelectronic component (E0), the first component (E1), and the second component (E2) and the wiring substrate 1, and further, may also be formed between the mutually opposing surfaces of the optical wiring part 3 and the optoelectronic component (E0). Examples of the optical resin include epoxy-based resins, silicone resins, acrylic resins, and the like.

Similarly, as illustrated in FIG. 3, in the optoelectronic component mounting region (A0), the first component mounting region (A1), and the second component mounting region (A2), a filling resin (underfill material) is not formed to fill between the optoelectronic component (E0), the first component (E1), and the second component (E2) and the wiring substrate 1. In the example of FIG. 3, it is also possible that a filling resin is formed only within the recess 20 where the first component (E1) is mounted. Further, an optical resin may be formed between mutually opposing surfaces of the optoelectronic component (E0) (specifically, the light receiving/emitting part (E0L) of the optoelectronic component (E0)) and the optical wiring part 3 (specifically, the core part 311 of the optical wiring part 3). By forming an optical resin between the optoelectronic component (E0) and the optical wiring part 3, optical transmission between the light receiving/emitting part (E0L) of the optoelectronic component (E0) and the core part 311 of the optical wiring part 3 can be easily realized.

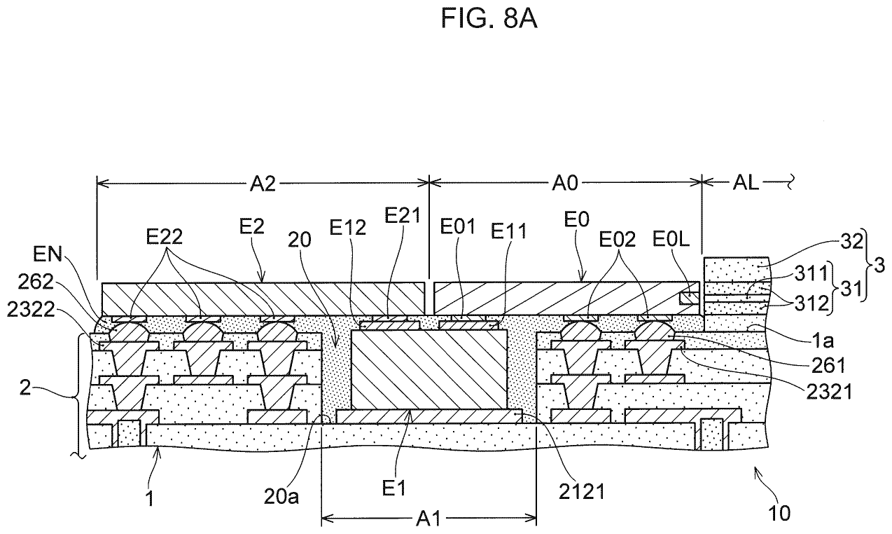

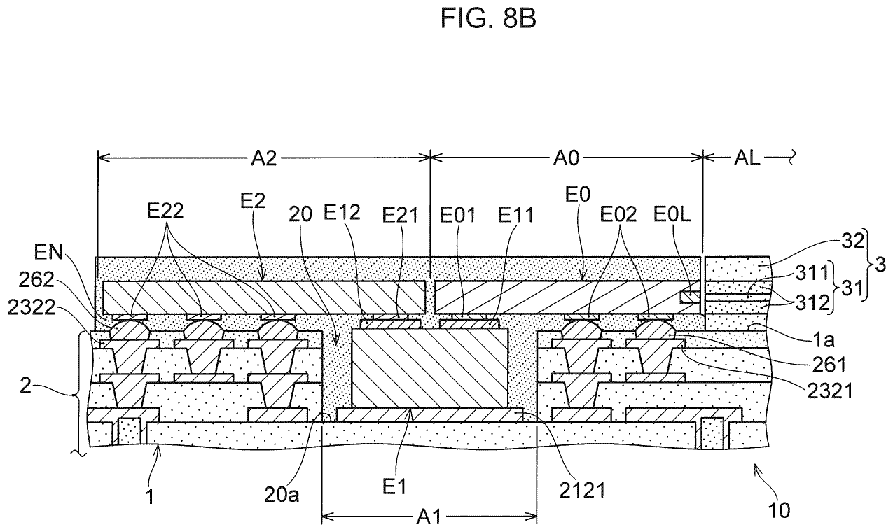

As illustrated in FIG. 8A, in the optoelectronic component mounting region (A0), the first component mounting region (A1), and the second component mounting region (A2), a filling resin (underfill material) (EN) may be formed to fill between the optoelectronic component (E0), the first component (E1), and the second component (E2) and the wiring substrate 1. In the example of FIG. 8A, the filling resin (EN) is formed to cover at least the lower surfaces of the optoelectronic component (E0) and the second component (E2), as well as the entire exposed surface of the first component (E1). Examples of the filling resin (underfill material) (EN) include resin materials such as epoxy-based resins and silicone resins. The filling resin (underfill material) (EN) may be formed from a single material or from multiple different materials. As an example, the filling resin formed within the recess 20 where the first component (E1) is mounted and the filling resin formed to cover the lower surfaces of the optoelectronic component (E0) and the second component (E2), as well as the entire exposed surface of the first component (E1), may be formed from different materials. Further, it is also possible that, between the mutually opposing surfaces of the optoelectronic component (E0) and the optical wiring part 3, no resin is formed, or an optical resin is formed. The optical resin facilitates optical transmission between the light receiving/emitting part (E0L) of the optoelectronic component (E0) and the core part 311 of the optical wiring part 3. When an optical resin is used as the filling resin (underfill material) (EN), the filling resin (underfill material) (EN) may be formed to fill between the optoelectronic component (E0), the first component (E1), and the second component (E2) and the wiring substrate 1, and further, may also be formed between the mutually opposing surfaces of the optical wiring part 3 and the optoelectronic component (E0). Examples of the optical resin include epoxy-based resins, silicone resins, acrylic resins, and the like.

As illustrated in FIG. 8B, the filling resin (EN) may be formed to cover the entire exposed surfaces of the optoelectronic component (E0), the first component (E1), and the second component (E2) and the wiring substrate 1. Examples of the filling resin (EN) include resin materials such as epoxy-based resins and silicone resins. Further, in the optoelectronic component mounting region (A0), the first component mounting region (A1), and the second component mounting region (A2), the filling resin (EN) may be formed to cover the entire exposed surfaces of the optoelectronic component (E0), the first component (E1), and the second component (E2) and the wiring substrate 1, except for the light receiving/emitting part (E0L) of the optoelectronic component (E0), leaving the light receiving/emitting part (E0L) of the optoelectronic component (E0) exposed without being covered. The filling resin (EN) may be formed from a single material or from multiple different materials. As an example, the filling resin formed within the recess 20 where the first component (E1) is mounted and the filling resin formed to cover the lower surfaces of the optoelectronic component (E0) and the second component (E2), as well as the entire exposed surface of the first component (E1), may be formed from different materials. Further, it is also possible that, between the mutually opposing surfaces of the optoelectronic component (E0) and the optical wiring part 3, no resin is formed, or an optical resin is formed. The optical resin facilitates optical transmission between the light receiving/emitting part (E0L) of the optoelectronic component (E0) and the core part 311 of the optical wiring part 3. When an optical resin is used as the filling resin (EN), the filling resin (EN) may be formed to fill the spaces between the optoelectronic component (E0), the first component (E1), and the second component (E2) and the wiring substrate 1, and further, may also be formed between the mutually opposing surfaces of the optical wiring part 3 and the optoelectronic component (E0). Examples of the optical resin include epoxy-based resins, silicone resins, acrylic resins, and the like.

Japanese Patent Application Laid-Open Publication No. 2013-257381 describes an optoelectronic module in which an electronic component such as an IC chip, an optoelectronic component such as a light emitting element or a light receiving element, and an optical wiring such as an optical waveguide are mounted on a surface of a wiring substrate. The electronic component is electrically connected to the optoelectronic component, and the optoelectronic component is optically connected to the optical wiring. The electronic component is electrically connected to the optoelectronic component via wiring patterns formed on the surface of the wiring substrate.

In the optoelectronic module described in Japanese Patent Application Laid-Open Publication No. 2013-257381, the connection between the electronic component and the optoelectronic component can become complex due to a structure of a substrate or arrangement of the wiring patterns. Specifically, the connection between the electronic component or the optoelectronic component and the wirings is performed via electrode terminals and solder. In this case, conditions for a connection process between the electronic component or the optoelectronic component and the wirings become complicated, alignment is not easy, and the connection may not be stable. As a result, an electrical signal transmitted between the electronic component and the optoelectronic component may not be stable. Therefore, it is thought that connection loss between the electronic component and the optoelectronic component may increase. Further, when capacity for optical transmission increases, it is thought that it may lead to a decrease in data speed due to the connection loss between the electronic component and the optoelectronic component.

A wiring substrate according to an embodiment of the present invention includes: a first component mounting region on a component mounting surface; an optoelectronic component mounting region; and an optical wiring that can be optically connected to an optoelectronic component. A recess is formed on the component mounting surface of the wiring substrate. The first component mounting region is provided in the recess. The first component mounting region at least partially overlaps with the optoelectronic component mounting region in a plan view.

A component-mounted wiring substrate according to an embodiment of the present invention includes: the above-described wiring substrate; and a first component that is accommodated in the recess and mounted in the first component mounting region. A first component conductive connecting member that can connect the optoelectronic component and the first component is formed on an electrode surface of the first component.

According to an embodiment of the present invention, a connection structure between the electronic component and the optoelectronic component becomes less complex. As a result, it is thought that conditions for a connection process and alignment are simplified, a connection distance between the electronic component and the optoelectronic component is shortened, and connection loss is suppressed. Further, according to an embodiment of the present invention, it is thought that a decrease in data speed due to connection loss between the electronic component and the optoelectronic component is suppressed.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an electrical wiring part having a recess and a component mounting region formed in the recess on a component mounting surface of the electrical wiring part; and
an optical wiring formed on the component mounting surface of the electrical wiring part such that the optical wiring is configured to optically connect to an optoelectronic component,
wherein the electrical wiring part has an optoelectronic component mounting region formed such that the component mounting region at least partially overlaps with the optoelectronic component mounting region.

2. The wiring substrate according to claim 1, wherein the electrical wiring part has an optoelectronic component conductor pad formed in the optoelectronic component mounting region on the component mounting surface, and an optoelectronic component conductive connecting member formed on the optoelectronic component conductor pad and configured to connect the optoelectronic component and the optoelectronic component conductor pad.

3. The wiring substrate according to claim 2, wherein the electrical wiring part has a second component mounting region formed on the component mounting surface such that the second component mounting region at least partially overlaps with the first component mounting region.

4. The wiring substrate according to claim 3, wherein the electrical wiring part has a second component conductor pad formed in the second component mounting region on the component mounting surface, and a second component conductive connecting member formed on the second component conductor pad and configured to connect a second component and the second component conductor pad.

5. The wiring substrate according to claim 1, further comprising:
a support member formed on the component mounting surface of the electrical wiring part such that the optical wiring is positioned on the support member.

6. The wiring substrate according to claim 1, further comprising:
a support substrate formed on the optical wiring on an opposite side with respect to the component mounting surface.

7. The wiring substrate according to claim 2, further comprising:
a support member formed on the component mounting surface of the electrical wiring part such that the optical wiring is positioned on the support member.

8. The wiring substrate according to claim 2, further comprising:
a support substrate formed on the optical wiring on an opposite side with respect to the component mounting surface.

9. A component-mounted wiring substrate, comprising:
the wiring substrate of claim 1;
a first component accommodated in the recess of the electrical wiring part such that the first component is mounted in the first component mounting region; and
a first component conductive connecting member formed on an electrode surface of the first component and configured to connect the optoelectronic component and the first component.

10. A component-mounted wiring substrate, comprising:
the wiring substrate of claim 1;
a first component accommodated in the recess of the electrical wiring part such that the first component is mounted in the first component mounting region; and
a metal formed on an electrode surface of the first component and configured to metal bond the optoelectronic component and the first component.

11. The component-mounted wiring substrate according to claim 9, further comprising:
an optoelectronic component mounted in the optoelectronic component mounting region of the electrical wiring part; and
a second component mounted in a second component mounting region of the electrical wring part,
wherein the second component mounting region of the electrical wiring part is formed on the component mounting surface such that the second component mounting region at least partially overlaps with the first component mounting region.

12. The component-mounted wiring substrate according to claim 11, wherein no filling resin is formed between the optoelectronic component, the first component, the second component, and the wiring substrate.

13. The component-mounted wiring substrate according to claim 11, further comprising:
a filling resin filling spaces between the optoelectronic component, the first component, the second component, and the wiring substrate.

14. The component-mounted wiring substrate according to claim 13, wherein the filling resin is formed such that the filling resin is covering entire exposed surfaces of the optoelectronic component, the first component, and the second component.

15. The component-mounted wiring substrate according to claim 11, wherein the wiring substrate has a second component conductor pad formed in the second component mounting region on the component mounting surface of the electrical wiring part, and a second component conductive connecting member formed on the second component conductor pad and configured to connect a second component and the second component conductor pad.

16. The component-mounted wiring substrate according to claim 10, further comprising:
an optoelectronic component mounted in the optoelectronic component mounting region of the wiring substrate; and
a second component mounted in a second component mounting region formed on the component mounting surface such that the second component mounting region at least partially overlaps with the first component mounting region.

17. The component-mounted wiring substrate according to claim 16, wherein no filling resin is formed between the optoelectronic component, the first component, the second component, and the wiring substrate.

18. The component-mounted wiring substrate according to claim 16, further comprising:
a filling resin filling spaces between the optoelectronic component, the first component, the second component, and the wiring substrate.

19. The component-mounted wiring substrate according to claim 18, wherein the filling resin is formed such that the filling resin is covering entire exposed surfaces of the optoelectronic component, the first component, and the second component.

20. The component-mounted wiring substrate according to claim 16, wherein the wiring substrate has a second component conductor pad formed in the second component mounting region on the component mounting surface, and a second component conductive connecting member formed on the second component conductor pad and configured to connect a second component and the second component conductor pad.
